(19) United States
(12) Patent Application Publication
(10) Pub. No.: US 2024/0288499 A1
(43) Pub. Date: Aug. 29, 2024

(54) THERMAL SIGNATURE OF BATTERIES

(71) Applicant: Apple Inc., Cupertino, CA (US)

(72) Inventors: Mona Shirpour, San Jose, CA (US); Shabab Amiruddin, Pacifica, CA (US); Karthikeyan Kumaresan, Sunnyvale, CA (US); Aswin Karthik Manohar, Fremont, CA (US)

(21) Appl. No.: 18/583,709

(22) Filed: Feb. 21, 2024

Related U.S. Application Data
(60) Provisional application No. 63/548,775, filed on Feb. 1, 2024.
(60) Provisional application No. 63/486,607, filed on Feb. 23, 2023.

(51) Int. Cl. G01R 31/367; G01N 25/48; G01N 25/72; G01R 31/392

(52) U.S. Cl. CPC G01R 31/367; G01N 25/4866; G01N 25/72; G01R 31/392

(57) ABSTRACT

This disclosure relates generally to measuring thermal signature of battery cells and components by measuring DSC curves of battery components.

### PRIORITY

This patent application claims priority to U.S. Provisional Patent Application No. 63/486,607 filed on Feb. 23, 2023, and U.S. Provisional Patent Application No. 63/548,775 filed on Feb. 1, 2024. The above-identified applications are incorporated herein by reference in their entireties.

### FIELD

This disclosure relates generally to measuring thermal signature of battery cells and components.

### BACKGROUND

Lithium ion (Li-ion) battery cells are widely used as the power sources in consumer electronics. Consumer electronics need Li-ion battery cells which can deliver higher volumetric energy densities and sustain more discharge-charge cycles.

Identification of batteries and battery components can be desirable to determine the use of a particular battery, or to monitor the presence or absence of specific battery components.

### SUMMARY

In a first aspect, the disclosure is directed to a method of generating a reference DSC curve corresponding to a battery cell. A DSC curve of a battery component is obtained. Then one or more properties of the DSC curve are determined.

In a second aspect, the disclosure is directed to a method of characterizing a DSC curve of a battery cell. A DSC property selected from a local minimum, a local maximum, onset temperature of a local minimum, onset temperature of a local maximum, or combination thereof is identified within the DSC curve. The DSC property is associated with the characteristics of the battery component and/or battery cell. The association can correspond to comparison with a reference DSC curve.

In a third aspect, the disclosure is directed to identifying the similarity of a battery cell to a reference battery cell. The DSC curve of a battery component of a sample battery is generated. A DSC property is identified and compared to the same one or more properties of a reference DSC curve. The similarity of the sample battery cell to the reference battery cell is determined.

In some variations, the step of associating comprises determining the peak temperature of the local minimum or local maximum. In some variations, the step of associating comprises determining the area under a curve of the local minimum or local maximum. In some variations, the step of associating comprises determining the onset temperature of the onset temperature of the local minimum or local maximum.

In a fourth aspect, the disclosure is directed to a method of identifying a contaminant in a battery cell. A DSC curve of a battery component is generated. A DSC property is compared to the DSC property of a reference DSC curve of the component of a battery cell without the contaminant. The DSC property that does not appear in the reference DSC curve is identified to determine the presence of one or more contaminants in the battery cell.

The disclosure is directed to a method of determining the similarity of a battery component to a reference battery component. A DSC curve of the battery component is generated. A DSC property is determined. The DSC property is compared to a DSC property of a reference DSC curve corresponding to a reference battery component. If the DSC property is present in the reference DSC curve, the battery cell is similar to a battery cell comprising the reference battery component.

In variations of the foregoing aspects, the battery component can be selected from the cathode, separator, anode, and sealant. In one further variation, the battery component can be a cathode. In another further variation, the battery component can be an anode. In a still further variation, the battery component can be a separator. In another variation, the battery component can be a sealant. The one or more properties can include, without limitation or disclaimer, the temperature of one or more local maxima and/or local minima of the DSC curve. Alternatively, the one or more properties can include the peak temperature of decomposition of the battery component.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 depicts a top-down view of a battery cell, in accordance with an illustrative embodiment; and

FIG. 2 depicts a side view of a battery cell, in accordance with an illustrative embodiment;

FIG. 3 depicts three DSC measurements of an anode at three different stages of charge, in accordance with an illustrative embodiment;

FIGS. 4A and 4B depict the DSCs of two fully charged anodes, in accordance with an illustrative embodiment;

FIG. 4C depicts the DSC of an example anode from batteries at charge states of 3.50 V, 4.30 V, 4.47 V, and 4.50 V, in accordance with illustrative embodiments;

FIG. 4D depicts the DSC of two example anodes, in accordance with illustrative embodiments;

FIGS. 5A and 5B depict the DSCs of two fully charged cathodes with different coating chemistry, in accordance with an illustrative embodiment;

FIG. 5C depicts the DSC of an example cathode from batteries at charge states of 3.50 V, 4.30 V, 4.47 V, and 4.50 V, in accordance with illustrative embodiments;

FIG. 5D depicts the DSC of three different example cathodes, in accordance with illustrative embodiments;

FIGS. 6A and 6B depict DSCs of two separators with different coating chemistry, in accordance with illustrative embodiments;

FIG. 6C depicts the DSC curve for two different separator materials; in accordance with illustrative embodiments;

FIG. 7A depicts example DSC curves for a unimodal sealant and a bimodal sealant, in accordance with illustrative embodiments;

FIG. 7B depicts an expanded view of the DSC curve of FIG. 7A, in accordance with illustrative embodiments; and

FIG. 7C depicts example DSC curves for a unimodal sealant and a bimodal sealant, in accordance with illustrative embodiments.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Li-ion battery cells store energy by moving lithium ions from the cathode to the anode during the charging process. This stored energy can be utilized by moving lithium from the anode to the cathode during discharging process. The total amount of lithium in the cell can be one of the factors that determine the energy density of the Li-ion battery cell.

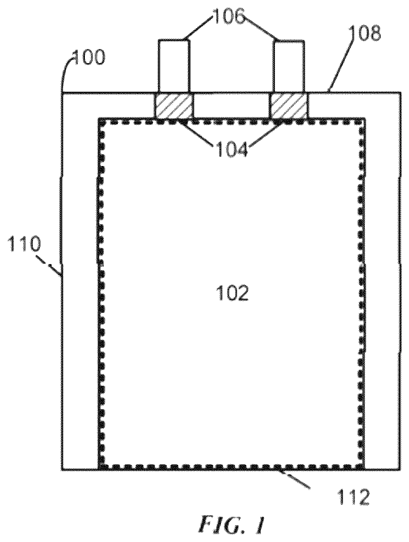

FIG. 1 presents a top-down view of a battery cell 100 in accordance with an embodiment. The battery cell 100 may correspond to a lithium-ion or lithium-polymer battery cell that is used to power a device used in a consumer, medical, aerospace, defense, and/or transportation application. The battery cell 100 includes a stack 102 containing a number of layers that include a cathode with a cathode active coating, a separator, and an anode with an anode active coating. More specifically, the stack 102 may include one strip of cathode (e.g., aluminum foil coated with a lithium compound) and one strip of anode (e.g., copper foil coated with graphite). The stack 102 also includes one strip of separator material (e.g., a microporous polymer membrane or non-woven fabric mat) disposed between the cathode and anode. The cathode, anode, and separator may be left flat in a planar configuration or may be wrapped into a wound configuration (e.g., a “jelly roll”). An electrolyte solution is disposed between each cathode and anode.

During assembly of the battery cell 100, the stack 102 can be enclosed in a pouch or container. The stack 102 may be in a planar or wound configuration, although other configurations are possible. In some variations, the pouch such as a pouch formed by folding a flexible sheet along a fold line 112. In some instances, the flexible sheet is made of aluminum with a polymer film, such as polypropylene. After the flexible sheet is folded, the flexible sheet can be sealed, for example, by applying heat along a side seal 110 and along a terrace seal 108. The flexible pouch may be less than or equal to 120 microns thick to improve the packaging efficiency of the battery cell 100, the density of battery cell 100, or both.

The stack 102 can also include a set of conductive tabs 106 coupled to the cathode and the anode. The conductive tabs 106 may extend through seals in the pouch (for example, formed using sealing tape 104) to provide terminals for the battery cell 100. The conductive tabs 106 may then be used to electrically couple the battery cell 100 with one or more other battery cells to form a battery pack. For example, the battery pack may be formed by coupling the battery cells in a series, parallel, or a series-and-parallel configuration. Such coupled cells may be enclosed in a hard case to complete the battery pack or may be embedded within an enclosure of a portable electronic device, such as a laptop computer, tablet computer, mobile phone, personal digital assistant (PDA), digital camera, and/or portable media player.

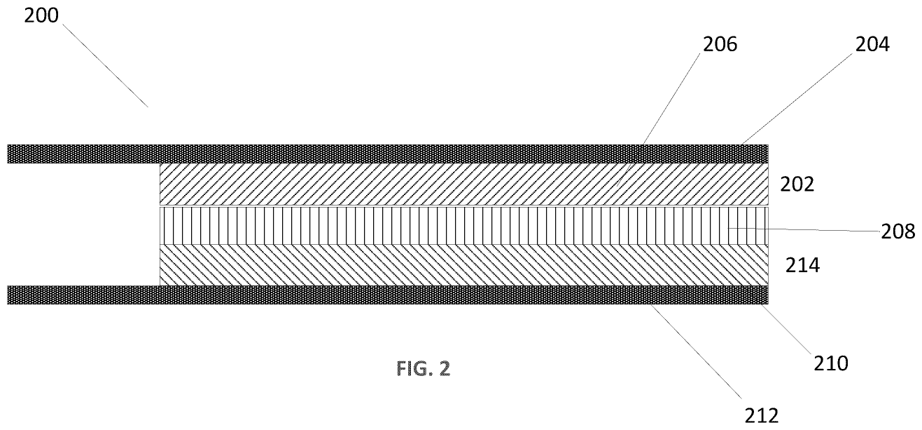

FIG. 2 presents a perspective view of a battery cell 200 (e.g., the battery cell 100 of FIG. 1) in accordance with the disclosed embodiments. The battery cell 200 includes a cathode 202. The cathode 202 includes a cathode current collector 204 and cathode active material layer 206. The battery cell 200 also includes an anode 214. The anode 214 include the anode current collector 212 and anode active material 210. A separator 208 is disposed between the cathode 202 and anode 214. During battery operation, and electrolyte fluid is disposed between cathode 202 and anode 214 and is in contact with separator 208.

To create the battery cell, cathode 202, separator 208, and anode 214 may be stacked in a planar configuration, or alternatively stacked and then wrapped into a wound configuration. The electrolyte fluid can then be added.

Each of the cathode, anode, electrolyte, separator, and sealant are often complex combinations of organic and inorganic compounds that often cannot be characterized precisely and using only one analytical technique. Differential scanning calorimetry (DSC) is a method allowing identification of a wide range of organic and inorganic materials even in small quantities. DSC precisely measures enthalpy changes due to changes in the physical and chemical properties of a material as a function of temperature or time.

In lithium-ion battery cells, the thermal reactions of cell constituents can be specific to each combination of electrodes (i.e., cathode and anode), electrolyte, and separator and at a specific state of battery cell charge. Aspects of the battery cell, including its identity, characterize the battery components from bulk level to nanoscale.

By conducting a DSC on each of the cathode, anode, separator, and sealant the composition and/or identity of a particular battery cell can be determined.

### Anode

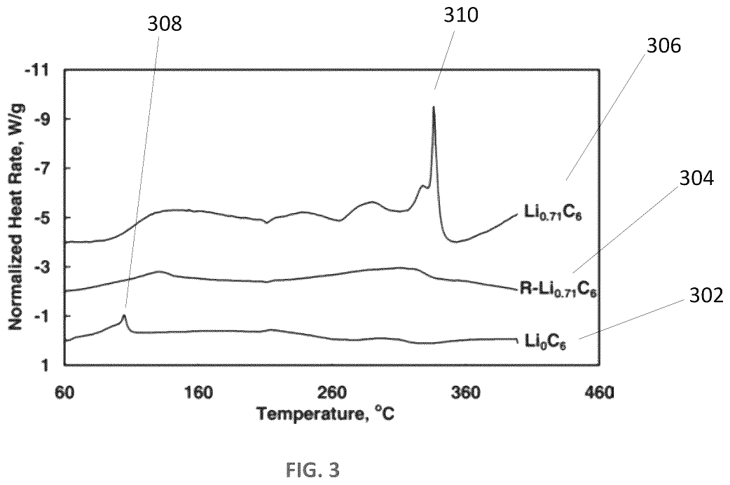

FIG. 3 depicts DSC curves corresponding to an anode at different stages of lithiation (or charge). DSC 302 corresponds to an unlithiated anode, DSC 304 corresponds to a partially lithiated anode, and DSC 306 a more highly lithiated anode. As the amount of lithium is added, reactions occur at the anode. In the DSC 302 of the unlithiated anode, peak 308 corresponds to the enthalpy of graphite converting into carbon without lithium. A “peak” as used herein can also be referred to as local maximum or a local minimum. In the DSC 306 of the lithiated anode, peak 310 corresponds to the enthalpy of graphite converting into carbon occurs at approximately 160° C. The interaction of the anode, lithium, and electrolytes results in decomposition of graphite at a higher temperature. Chemical species form the anode in different amounts, various other species can be observed at different stages of lithiation based on changes in the temperature of combustion.

The identity of the particular battery can be identified based on comparison of an anode to a reference pattern. For example, referring again to FIG. 3, measuring a sample anode at lithiation of 0.71 will be the same as DSC 306, including peak 310, if the electrolyte and anode are the same. However, variation in the anode and/or electrolyte will result in a different sample DSC than DSC 310.

DSC curves can be used to generate a reference DSC curve corresponding to a battery component. DSC curves can be used to identify the similarity of a battery cell to a reference battery component. In DSC measurements can be used to determine the presence of a contaminant (i.e., undesired chemical species) in a battery cell component. The DSC curve can be used to select a battery cell component. The DSC curve can be used to select a method of battery component preparation. In another variation, the identity of a battery cell component can be determined as the same or similar to another battery cell component.

In one variation, the battery component can be the cathode active material. In one variation, the battery component can be the anode. In one variation, the battery component can be the separator.

The methods described herein can be performed by measuring one or more properties of the DSC curve. In some variations, a property can be temperature of a local minimum or local maximum (i.e., a “peak”). In some variations, the peak is compared to another peak, and can be in a range (“similar” can refer to in one variation+/−1° C., in another variation+/−3° C., or in another variation+/−5° C.) to be similar to a reference peak or a peak of a battery cell component of a different battery or reference battery. In some variations, the property is a temperature difference between the peaks of a DSC curve as compared to a different DSC curve. All comparisons are of battery cells having the same charge state or amount of lithiation.

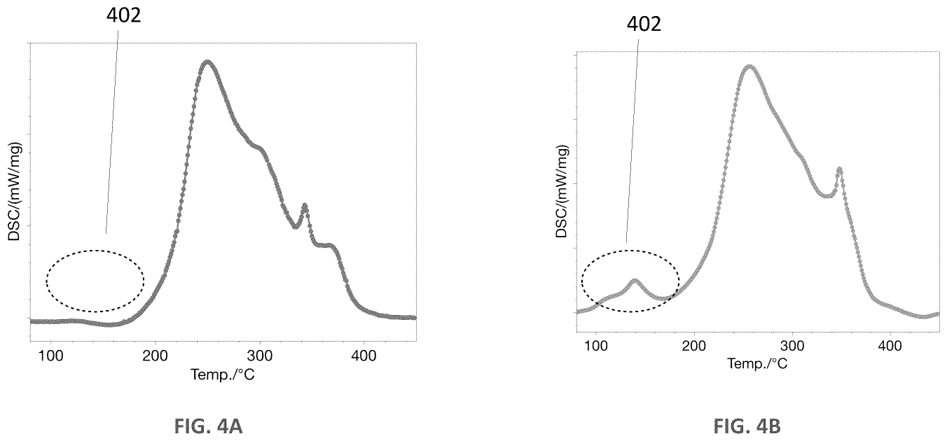

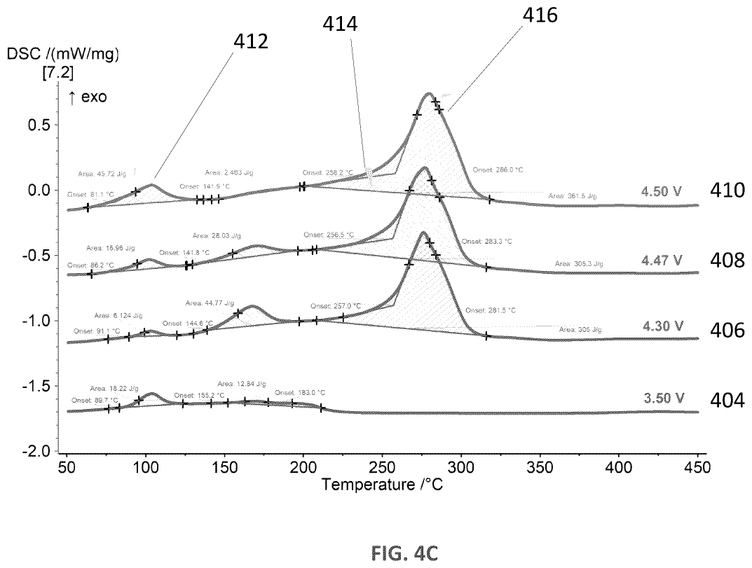

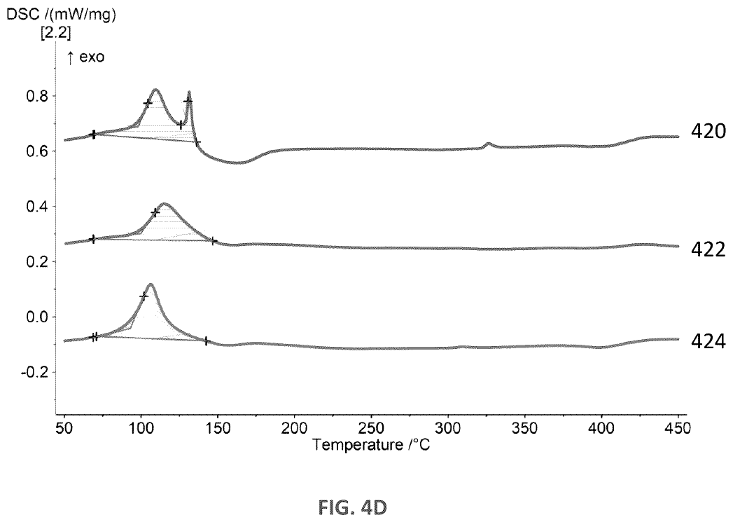

FIGS. 4A and 4B depict the DSCs of two fully charged anodes. The anodes have different coating chemistries. The DSC in FIG. 4B includes peak in region 402, which is a result of anode chemistry and electrolyte formulation. The peak in region 402 is known to be detrimental to performance of the battery cell. The absence of a peak in region 402 of FIG. 4A shows that the anode and coating method for the anode of FIG. 4A results in specific improvement in battery cell performance as compared to a battery cell incorporating the anode measured in FIG. 4B. Those skill in the art can choose not to use anodes with the coating chemistry of FIG. 4B, and instead use the coating chemistry of FIG. 4A.

FIG. 4C depicts the DSC of an example anode from batteries at charge states of 3.50 V (404), 4.30 V (406), 4.47 V (408), and 4.50 V (410). With respect to the 4.50 V (410), peak 412 corresponds to the LiF-containing solid electrolyte interphase (SEI). Peak 414 corresponds to the metastable SEI decomposition (e.g., R₂CO₃, LiRCO₃). Peak 416 corresponds to the SEI decomposition and collapse of the lithiated structure, oxidized by the electrolyte.

The area under the curve of peak 416 is the enthalpy of the composition; in various aspects, the enthalpy is an inherent of the material. Comparing the enthalpy of the same amount of anode material at a particular charge state can be a measurement to determine whether two material samples are the same. As can be observed in FIG. 4C, the enthalpy of composition of the anode varies by over 10× between 3.50 V and 4.50 V.

The charge state influences the DSC and chemical decomposition. With further reference to FIG. 4C, the quantity of different species is progressively lower at different peak values. All peaks reduce in amplitude from 4.50 V (410), to 4.47 V (408), to 4.30 V (406), to 3.50 V (404).

The onset temperature in the DSC curve can be measured and compared between two materials. Alternatively, the area under the curve corresponding to the enthalpy of the composition can be measured and compared between two compositions. A similarity between two variations can indicate a similarity between two anodes. Two anodes having an onset temperature within 8 degrees Celsius, and/or the enthalpy within 10% for an anode having the same mass and charge state indicates that the two anodes have the same composition.

FIG. 4D depicts the DSC of example anode 1 (420), example anode 2 (422), and example anode 3 (424). Example anode 1 (420) has two separate peaks corresponding to two compositions compared to a single composition in example anode 2 (422) and example anode 3 (424). The distinct two peaks of example anode 1 (420) show that this anode material is a different material from example anode 2 (422) and example anode 3 (424).

The electrolyte can change the pattern for both anode and cathode. The thermal signature can be that of the cathode, anode, and electrolyte.

In one variation, an anode and electrolyte, or alternatively a battery cell, can be selected over another anode and electrolyte (or alternatively battery cell) by obtaining an anode and electrolyte used in a battery cell, determining a DSC of the anode and electrolyte, and selecting the anode and electrolyte (or alternatively battery cell) having the DSC corresponding to the best battery cell function. In another variation, the identity of an anode and electrolyte (or alternatively battery cell) can be determined as the same or similar to another anode and electrolyte by measuring the DSC of the anode and electrolyte, confirming the location of the peaks as a function of temperature as compared to a reference battery cell (e.g. within +/−1° C., or within +/−2° C., or within +/−3° C.), or relative peaks, and thereby determining the anode and electrolyte (or alternatively battery cell) is the same as or different from the reference battery cell. All comparisons are of battery cells having the same charge state or amount of lithiation.

### Cathode

DSC measurements can be used to determine the presence of undesired chemical species in a cathode, or alternatively in a method of selecting a cathode, or a method of selecting a method of cathode preparation.

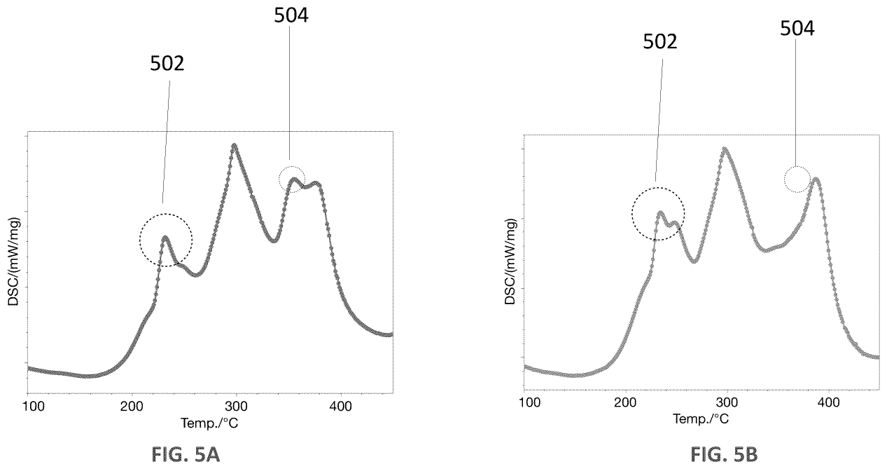

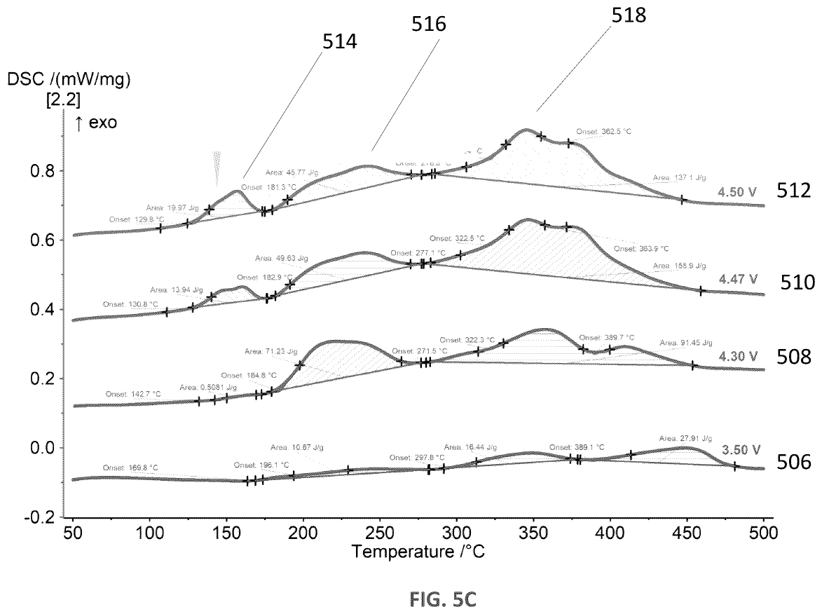

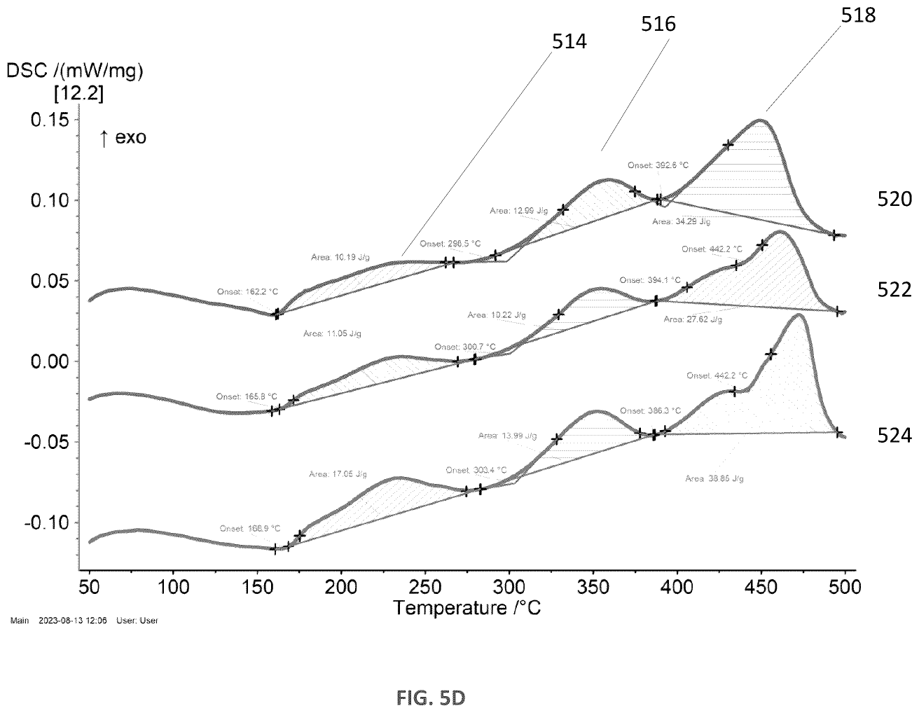

FIGS. 5A and 5B depict the DSCs of two fully charged cathodes with different coating chemistry. The DSC depicted in FIG. 5B includes an additional peak in region 502 as compared to the DSC of FIG. 5A. FIG. 5B lacks a peak at 504 that is present in FIG. 5A. In some variations, the peak in region 502 is known to be detrimental to performance of the battery cell. The absence of a peak in region 502 of FIG. 5A shows that the cathode and coating method for the cathode of FIG. 5A results in improved battery cell performance as compared to a battery cell incorporating the cathode measured in FIG. 5B. Those skill in the art can choose not to use cathode with the coating chemistry of FIG. 5B, and instead use the coating chemistry of FIG. 5A. In other variations, the cathode with the coating chemistry FIG. 5B can be useful at higher voltage operating conditions.

The change of the peaks in intensity and relative ratios at different states of charge can depends on both the cathode coating chemistry and the electrolyte formulation.

FIG. 5C depicts the DSC of an example cathode from batteries at charge states of 3.50 V (506), 4.30 V (508), 4.47 V (510), and 4.50 V (512). With respect to the 4.50 V (512), peak 514 corresponds to the conversion of CoO₂ to Co₃O₄. Peak 516 corresponds to conversion of Co₃O to CoO. Peak 518 corresponds to conversion of CoO to Co and cathode structure collapse.

The area under the curve of peak 518 is the enthalpy of the composition; in various aspects, the enthalpy is an inherent of the material. Comparing the enthalpy of the same amount of cathode material at a particular charge state can be a measurement to determine whether two material samples are the same. As can be observed in FIG. 5C, the enthalpy of composition of the cathode varies IS 3-5× lower at 3.50 V than at 4.50 V.

The charge state influences the DSC and chemical decomposition. With further reference to FIG. 5C, the quantity of different species is progressively lower at different peak values. All peaks reduce in amplitude from 4.50 V (512), to 4.47 V (510), to 4.30 V (508), to 3.50 V (506).

The onset temperature in the DSC curve can be measured and compared between two cathode materials. Alternatively, the area under the curve corresponding to the enthalpy of the composition can be measured and compared between two compositions. A similarity between two variations can indicate a similarity between two cathodes. Two cathodes having an onset temperature within 8 degrees Celsius at various points, and/or an enthalpy within 10% for a cathode having the same mass and charge state, indicates that the two cathodes have the same composition.

FIG. 5D depicts the DSC of example cathode 1 (520), example cathode 2 (522), and example cathode 3 (524). Example cathode 1 (520) has a larger enthalpy related to oxidation of CoO to Co and cathode structure collapse (peak 518) than example cathode 2 (522), but a smaller area of peak 518 than example cathode 3 (524). Additionally, peak 518 of example cathode 3 (524) has a shoulder corresponding to peak 518, and to a lesser extent example cathode 2 has a shoulder. Peak 516, corresponding to the enthalpy of conversion of Co₃O to CoO, has a larger area in example cathode 2 than example cathodes 1 or 3. Peak 514, corresponding to the enthalpy of CoO₂ to Co₃O₄, appears roughly equivalent to example alloy 520 and example alloy 524. The onset temperature is similar for each of peaks 514, 516, and 518 between each of examples 520, 522, and 524.

The electrolyte can change the pattern for both anode and cathode. The thermal signature can also be affected by the cathode, anode, and electrolyte.

Differences can correspond to a cathode dopant, composition, and thickness of the cathode coating. In some variations, the different can correspond to a difference in electrolyte composition.

### Separator

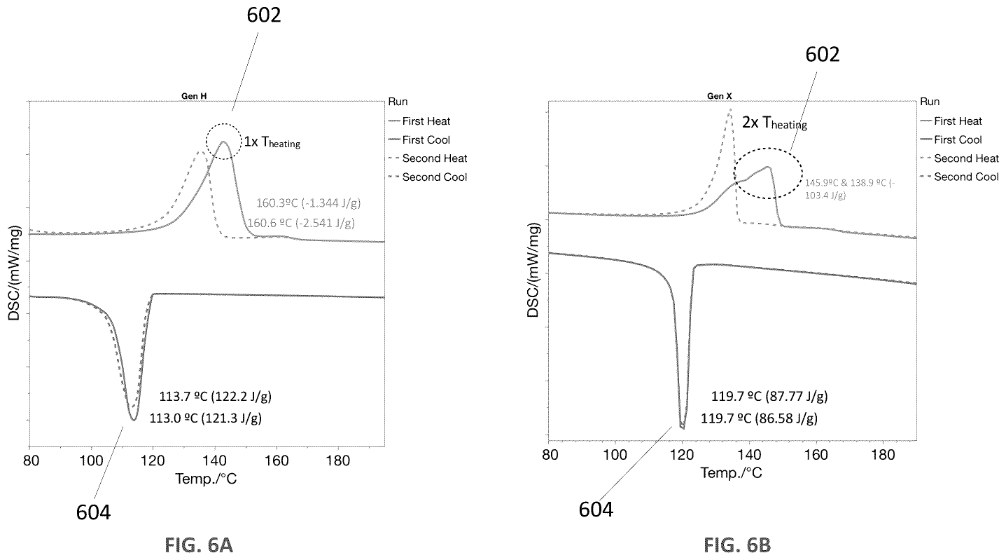

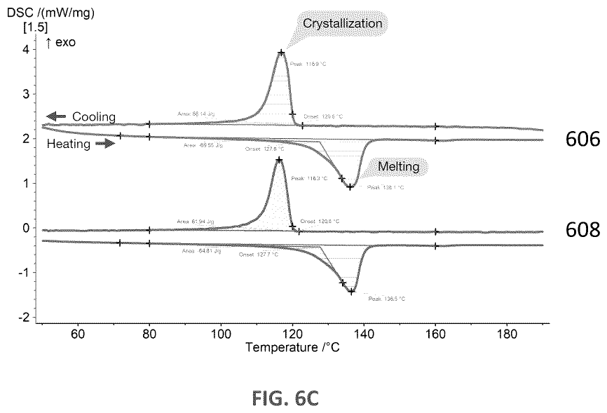

Separators can also be compared, according to methods described herein. The DSC in FIGS. 6A and 6B depict DSCs of two separators having different coatings. Peak 602 shows the first heating curve and temperature of decomposition. Peak 604 shows the peak temperature of cooling. Peak 602 of DSC of FIG. 6A shows decomposition at a higher temperature than the DSC of FIG. 6B. The higher temperature of decomposition is the result of an improved separator, which in the case of FIG. 6B is a function of the improved coating.

FIG. 6C depicts the DSC curve for two different separator materials: separator sample 1 (606) and separator sample 2 (608). The only difference between separator sample 1 (606) and separator sample 2 (608) is the ceramic coating. The crystallization peak, onset, and enthalpy are the same for separator sample 1 (606) and separator sample 2 (608). The similarity indicates that the separator material, and that difference in ceramic coating did not play a role in the measurement.

### Sealant

Sealants can also be compared, according to methods described herein.

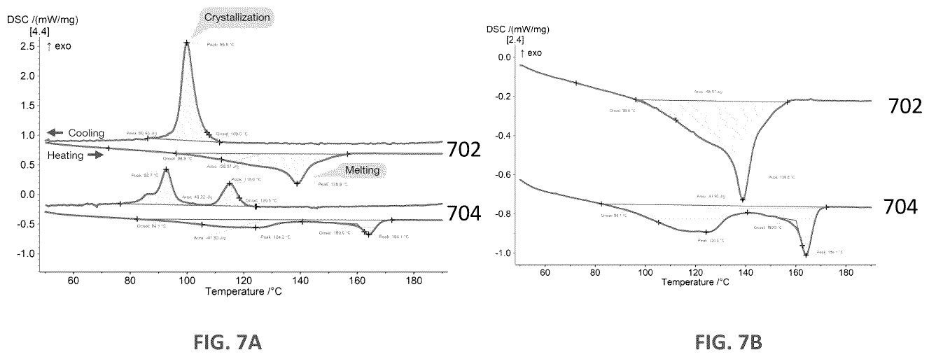

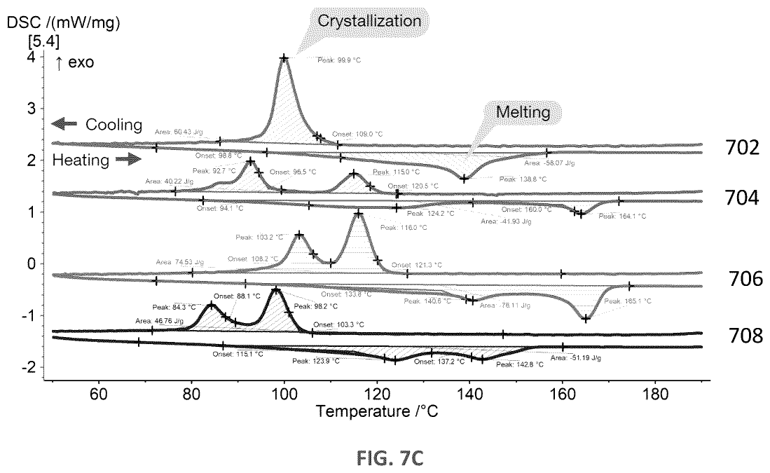

FIG. 7A depicts example DSC curves for a unimodal sealant 702 and a bimodal sealant 704. FIG. 7B depicts an expanded view of the DSC curve of FIG. 7A. DSC curve 702 depicts a unimodal sealant with a single crystallization peak and a single melting peak. The single peaks indicate a single layer phase. DSC curve 704 is of a bimodal sealant with two crystallization peaks, the first with a shoulder, and two melting peaks. Further, the onset of crystallization, and peak crystallization, along with the onset of melting and peak melting point were different for unimodal sealant 702 and bimodal sealant 704. No chemical reactions were observed; only differences in peaks indicating that the chemical compositions were different.

FIG. 7C depicts example DSC curves for a unimodal sealant 702 and a bimodal sealant 704. DSC curve 702 and 704 are the same as those in FIG. 7A. DSC curves 706 and 708 are bimodal sealants with two crystallization peaks and two melting peaks. Further, the onset temperature of crystallization, peak crystallization temperature, onset temperature of melting point, and peak melting point were different for each of bimodal sealants 704, 706, and 708, respectively. This indicates that each of the four sealants corresponding to DSC curves 702, 704, 706, and 708 is a different material, one from the other.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

We claim:

1. A method of generating a reference DSC curve corresponding to a battery cell comprising:
obtaining a DSC curve of a battery component; and
determining a DSC property of the DSC curve.

2. The method of claim 1, wherein the battery component is selected from a cathode, a separator, an anode, and a sealant.

3. The method of claim 1, wherein the DSC property is selected from a local minimum, a local maximum, an area under the curve of a local maximum, an area under the curve of a local minimum, an onset temperature of a local minimum, an onset temperature of a local maximum, and a combination thereof.

4. The method of claim 1, wherein the DSC property comprises a temperature of one or more local maxima and/or local minima of the DSC curve.

5. The method of claim 1, wherein the DSC property comprises a peak temperature of decomposition of the battery component.

6. A method of characterizing a DSC curve of a battery cell comprising:
generating the DSC curve of a battery component;
identifying a DSC property selected from a local minimum, a local maximum, an area under the curve of a local maximum, an area under the curve of a local minimum, an onset temperature of a local minimum, an onset temperature of a local maximum, and a combination thereof within the DSC curve; and
associating the DSC property with a characteristic of the battery component or battery cell.

7. The method of claim 6, wherein the battery component is selected from a cathode, a separator, an anode, and a sealant.

8. The method of claim 6, wherein the DSC property comprises the peak temperature of the local minimum or local maximum.

9. The method of claim 6, wherein the DSC property comprises the area under a curve of a local minimum or a local maximum.

10. The method of claim 6, wherein the DSC property comprises the onset temperature of the onset temperature of the local minimum or local maximum.

11. The method of claim 6, wherein the DSC property comprises the peak temperature of decomposition.

12. The method of claim 6, wherein the DSC property comprises a distance of one of the local minimum or the local maximum from a second one of the local minimum or local maximum.

13. A method of identifying a similarity of a battery cell to a reference battery cell comprising:
generating a DSC curve of a battery component of a sample battery cell; and
comparing a DSC property of the sample battery cell to a reference DSC property of the reference battery cell to identify the similarity of the battery cell to a reference battery cell.

14. The method of claim 13, wherein the battery component is selected from a cathode, a separator, an anode, and a sealant.

15. The method of claim 13, wherein the DSC property comprises one or more peak temperature of decomposition.

16. The method of claim 13, wherein the DSC property comprises one of a total local minimum and a total local minimum.

17. The method of claim 13, wherein the step of associating comprises measuring a difference in temperature from a first local minimum or maximum to a second local minimum or local maximum.

18. The method of claim 13, wherein the step of associating comprises determining the peak temperature of a local minimum or a local maximum.

19. The method of claim 13, wherein the step of associating comprises determining an area under a curve of the local minimum or local maximum.

20. The method of claim 13, wherein the step of associating comprises determining an onset temperature of the onset temperature of the local minimum or local maximum.

21. A method of determining a contaminant in a battery cell comprising:
generating a DSC curve of a battery component of the battery cell;
comparing a DSC property of the DSC curve to a reference DSC curve of the battery component of the battery cell without contaminants; and
identifying a DSC property does not appear in the reference DSC curve to determine the presence of one or more contaminants in the battery cell.

22. A method of determining the similarity of a battery component to a reference battery component comprising:
generating a DSC curve of the battery component of a battery cell;
determining a DSC property of the DSC curve; and
comparing the DSC property to a DSC property of a reference DSC curve of the battery component of a reference battery cell;
wherein if the DSC property is present in the reference DSC curve, the battery cell is similar to a battery cell comprising the reference battery component.
